(19) United States
(12) Patent Application Publication
(10) Pub. No.: US 2011/0240592 A1
(43) Pub. Date: Oct. 6, 2011

(54) TEXTURE PROCESSING LIQUID FOR TRANSPARENT CONDUCTIVE FILM MAINLY COMPOSED OF ZINC OXIDE AND METHOD FOR PRODUCING TRANSPARENT CONDUCTIVE FILM HAVING RECESSES AND PROJECTIONS

(75) Inventors: Masahide Matsubara, Chiba (JP); Satoshi Okabe, Tokyo (JP)

(73) Assignee: MITSUBISHI GAS CHEMICAL COMPANY, INC., TOKYO (JP)

(21) Appl. No.: 13/123,179

(22) PCT Filed: Oct. 5, 2009
(86) PCT No.: PCT/JP2009/067360

§ 371 Date: Jun. 24, 2011

(30) Foreign Application Priority Data
Oct. 29, 2008 (JP) 2008-278260

(51) Int. Cl. H05K 13/00; C09K 13/00; C09K 13/06; B05D 3/10; C23F 1/00

(52) U.S. Cl. 216/13; 252/79.1; 252/79.4

(57) ABSTRACT

A texture processing liquid for a transparent conductive film for realizing a high photoelectric conversion efficiency in a thin solar cell and a method for producing a transparent conductive film are provided.

The surface of a transparent conductive film mainly composed of zinc oxide is brought into contact with an aqueous solution containing a polyacrylic acid or a salt thereof and an acidic component to form a texture having recesses and productions, and after the process, the surface of the transparent conductive film having recesses and projections is further subjected to a contact treatment with an alkaline aqueous solution.

### TECHNICAL FIELD

The present invention relates to a processing liquid for imparting a texture having recesses and projections onto the surface of a transparent conductive film mainly composed of zinc oxide which is used for the manufacture of a thin film solar cell having a high photoelectric conversion efficiency and to a method for producing a transparent conductive film having recesses and projections.

### BACKGROUND ART

In recent years, due to a growing interest in an exhaustion problem of fossil energy, photovoltaic generation (solar cell) that is its alternative energy is watched. In the solar cell market, silicon based solar cells whose technical development is advanced have been put into practical use from old, and above all, crystalline silicon solar cells with an excellent photoelectric conversion efficiency are widely used. But, as for the crystalline silicon solar cells, because of difficulty in thin film formation from the standpoint of manufacture, a large quantity of silicon as a raw material is consumed, and therefore, its uneasy supply is regarded problematic. Also, since it may be impossible to realize a large area at the mass production, there is involved such a problem that the production cost is expensive. On the other hand, solar cells using amorphous silicon as a photoelectric conversion layer are watched as a measure capable of solving these problems. Since amorphous silicon is subjected to film formation by means of CVD (chemical vapor deposition), not only the film thickness is freely controllable, but large-sized. production can be achieved. Thus, this technical development is being advanced at present.

In an amorphous silicon thin film solar cell, when the film thickness of an i-layer is thick, a tangling bond (a defect in the film) increases, leading to a lowering of the efficiency. Thus, it is necessary to make the thickness of a photoelectric conversion layer thereof thin. For that reason, it becomes necessary to develop an optical confinement technology effectively utilizing the incident light.

The optical confinement technology refers to a technology for forming a texture having recesses and projections at an interface between a photoelectric conversion layer and .a transparent conductive layer and allowing light to scatter at that interface to prolong an optical path length, thereby increasing the absorption of light in the photoelectric conversion layer.

Also, p-type, i-type and n-type amorphous silicon layers are subjected to film formation by means of CVD in an upper part of the transparent conductive layer. In this connection, when a projected part is sharp, or when a recessed part is deep, coverage of the p-type silicon layer is deteriorated, and therefore, a shape with favorable coverage is desirable.

The transparent conductive film having recesses and projections on the surface thereof is, for example, obtained by forming a tin oxide film on a glass substrate by means of CVD. However, since manufacturers of a transparent electrode-equipped glass substrate to be produced by such a manufacturing method are limited, the supply is uneasy.

Also, there is studied a method in which after the film formation of a zinc oxide film on a glass substrate by means of sputtering, a treatment with an acid or an alkali is performed to form recesses and projections. Patent Document 1 discloses a method for manufacturing a substrate for solar cell, which is characterized by forming a transparent conductive film composed of zinc oxide on a substrate and etching the transparent conductive film with an acidic or alkaline aqueous solution, thereby forming recesses and projections on the surface thereof. Patent Document 2 discloses a method for manufacturing a substrate for solar cell, which is characterized by forming a transparent conductive film composed of zinc oxide on a substrate and etching the transparent conductive film with an etching liquid composed of an acidic or alkaline aqueous solution at least two times, thereby forming recesses and projections on the surface thereof.

However, by merely performing the simple etching treatment with an acidic or alkaline solution according to such a technology, the optical confinement effect is not sufficient, and as a result, the generating efficiency is not sufficient.

[Patent Document 1] JP-A-11-233800

[Patent Document 2] JP-A-2004-119491

### BRIEF DESCRIPTION OF THE DRAWINGS

FIG. 1 is a diagrammatic view of an apparatus used in the film formation of a transparent conductive film mainly composed of zinc oxide.

FIG. 2 is a diagrammatic sectional view showing a structure of a solar cell fabricated using a roughing technology on the surface of a transparent conductive film according to the present invention.

FIG. 3 is a secondary electron image (observation magnification: 50,000 times) of the surface of a transparent conductive film mainly composed of zinc oxide after the processing treatment in Example 17.

FIG. 4 is a secondary electron image (observation magnification: 50,000 times) of the surface of a transparent conductive film mainly composed of zinc oxide after the processing treatment in Example 18.

FIG. 5 is a secondary electron image (observation magnification: 50,000 times) of the surface of a transparent conductive film mainly composed of zinc oxide after the processing treatment in Comparative Example 7.

FIG. 6 is a secondary electron image (observation magnification: 50,000 times) of the surface of a transparent conductive film mainly composed of zinc oxide after the processing treatment in Comparative Example 8.

FIG. 7 is a secondary electron image (observation magnification: 50,000 times) of the surface of a transparent conductive film mainly composed of zinc oxide after the processing treatment in Comparative Example 11.

FIG. 8 is a secondary electron image (observation magnification: 50,000 times) of the surface of a transparent conductive film mainly composed of zinc oxide after the processing treatment in Comparative Example 12.

### EXPLANATIONS OF LETTERS OR NUMERALS

1: Charge/discharge chamber
2: Substrate tray
3: Film formation chamber
4: Heater
5: Roughing exhaust system
6: Gas line
7: Cathode
8: Power source
9: High vacuum exhaust system
11: Glass substrate
12: Transparent electrode (aluminum oxide (2% by mass)—containing zinc oxide film)
13: p-Type amorphous silicon layer
14: i-Type amorphous silicon layer
15: n-Type amorphous silicon layer
16: Transparent conductive layer (gallium-doped zinc oxide film)
17: sack-side metal electrode (silver)
18a, 18b: Electrode

### DISCLOSURE OF THE INVENTION

### Problems to be Solved by the Invention

As described above, according to the technologies which have hitherto been disclosed, the optical confinement effect is not sufficient, and it may be impossible to obtain a high photoelectric conversion efficiency. In view of the foregoing problems, the present invention has been made and is to provide a texture processing liquid for a transparent conductive film for the purpose of obtaining a high photoelectric conversion efficiency and a processing method.

### Means for Solving the Problems

According to the present invention, a texture processing liquid capable of forming a texture having recesses and projections on the surface of a transparent conductive film mainly composed of zinc oxide so as to enhance an optical confinement effect is characterized by an aqueous solution containing a polyacrylic acid. or a salt thereof and an acidic component. Also, a processing method of the texture is characterized by after a contact treatment with the foregoing texture processing liquid, subjecting the surface of the transparent conductive film to a contact treatment with an alkaline aqueous solution, thereby enhancing the photoelectric conversion efficiency.

That is, the gist of the invention of the present application is as follows.

1. A texture processing liquid comprising an acidic aqueous solution containing a polyacrylic acid or a salt thereof and an acidic component, which is used for the formation of a texture having recesses and projections on the surface of a transparent conductive film mainly composed of zinc oxide in a manufacturing process of a solar cell including the transparent conductive film. 2. The texture processing liquid as set forth above in 1, wherein a pH value of the acidic aqueous solution is not more than 6.5.
3. The texture processing liquid as set forth above in 1, wherein a weight average molecular weight of the polyacrylic acid is from 2,000 to 10,000.
4. The texture processing liquid as set forth above in 1, wherein the salt of polyacrylic acid is polyammonium acrylate.
5. The texture processing liquid as set forth above in 1, wherein a concentration of the polyacrylic acid or its salt is from 0.1% by mass to 3.0% by mass.
6. The texture processing liquid as set forth above in 1, wherein the acidic component is one or more members selected among acetic acid, citric acid, lactic acid, malic acid, glycolic acid, tartaric acid, hydrochloric acid, sulfuric acid and nitric acid.
7. The texture processing liquid as set forth above in 1, wherein a concentration of the acidic component is from 0.01% by mass to 30% by mass.
8. A method for producing a transparent conductive film comprising fabricating a transparent conductive film mainly composed of zinc oxide on a substrate, bringing the transparent conductive film into contact with the texture processing liquid as set forth in any one of claims 1 to 7 to form a texture having recesses and projections on the surface of the transparent conductive film, and then subjecting the surface of the texture to a contact treatment with an alkaline aqueous solution having a pH value of 12 or more.
9. The method for producing a transparent conductive film as set forth above in 8, wherein the alkaline aqueous solution contains one or more members selected among sodium hydroxide, potassium hydroxide, tetramethylammonium hydroxide, ammonia, monoethanolamine and methyl ethanolamine.
10. The method for producing a transparent conductive film as set forth above in 8 or 9, wherein the transparent conductive film is one used for solar cells.

### EFFECTS OF THE INVENTION

In a manufacturing process of a solar cell including a transparent electrode layer mainly composed of zinc oxide, by bringing the surface of a transparent electrode layer mainly composed of zinc oxide into contact with a processing liquid containing a polyacrylic acid or a salt thereof and an acidic component to give a texture having recesses and projections onto the surface of the transparent electrode layer and further subjecting it to a contact treatment with an alkaline aqueous solution, a recess and projection shape having not only a high optical confinement effect but favorable coverage can be fabricated, and a thin film solar cell with a high photoelectric conversion efficiency can be manufactured.

### BEST MODES FOR CARRYING OUT THE INVENTION

### [Texture Processing Liquid]

The texture processing liquid of the present invention is a processing liquid which is used for the formation of a texture having recesses and projections on the surface of a transparent conductive film mainly composed of zinc oxide in a manufacturing process of a solar cell including the transparent conductive film and which comprises an acidic aqueous solution containing a polyacrylic acid or a salt thereof and an acidic component.

### <<Polyacrylic Acid>>

The texture processing liquid of the present invention contains a polyacrylic acid or a salt thereof. The polyacrylic acid is a free acid, and examples of its salt include a potassium salt, an ammonium salt, a sodium slat, an amine salt and so on, with an ammonium salt being especially preferable.

A weight average molecular weight (Mw) of the polyacrylic acid or its salt is preferably from 2,000 to 10,000, more preferably from 3,000 to 8,000, and especially from 4,000 to 6,000. When the average molecular weight is 2,000 or more, a control effect of the recess and projection shape is obtainable; whereas when it is not more than 10,000, the polyacrylic acid or its salt is not adsorbed onto the surface of the film mainly composed of zinc oxide more than the necessity, and an etching rate of the film mainly composed of zinc oxide is not conspicuously lowered.

The polyacrylic acid or its salt is industrially available, and at the preparation of the processing liquid of the present invention, marketing products can be used. The polyacrylic acid or its salt is commercially available as trade names, for example, SHALLOL (registered trademark) Series of Dai-ichi Kogyo Co., Ltd., polyacrylic acid or salts thereof of Sigma-Aldrich Japan K. K., ARON (registered trademark) Series of Toagosei Co., Ltd., or the like.

An addition amount of the polyacrylic acid or its salt is preferably in the range of from 0.1 to 3.0% by mass. The addition amount of the polyacrylic acid or its salt is more preferably from 0.2% by mass to 2% by mass, and especially from 0.3% by mass to 1% by mass. When the addition amount of the polyacrylic acid or its salt is 0.1% by mass or more, a recess and projection shape with an excellent optical confinement effects is obtainable; whereas when it is not more than 3.0% by mass, the polyacrylic acid or its salt is not adsorbed onto the surface of the film mainly composed of zinc oxide more than the necessity, so that an etching rate of the film mainly composed of zinc oxide is not conspicuously lowered.

### <<Acidic Component>>

The texture processing liquid of the present invention contains an acidic component. As the acidic component, usual organic acids or inorganic acids can be used, and organic acids, for example, acetic acid, citric acid, lactic acid, malic acid, glycolic acid, tartaric acid, or the like, or inorganic acids, for example, hydrochloric acid, sulfuric acid, nitric acid, or the like, are preferably exemplified. The acid component is preferably one or more members selected among them are preferable.

A concentration of the acidic component of the texture processing liquid is preferably 0.01% by mass or more and not more than 30% by mass. The concentration of the acidic component is more preferably from 0.05% by mass to 10% by mass, and especially preferably from 0.1% by mass to 5% by mass. When the concentration of the acidic component is 0.01% by mass or more, a lowering of the etching rate with an increase of the zinc concentration in the processing liquid is not caused, and hence, such is preferable. On the other hand, when the concentration of the acidic component is not more than 30% by mass, the etching rate is not excessively fast, and the controllability of etching is favorable, and hence, such is preferable.

The texture processing liquid of the present invention makes it possible to form a favorable texture. Though the reason for this has not been thoroughly elucidated yet, it may be assumed as follows. Since the polyacrylic acid or its salt contained in the texture processing liquid of the present invention is heterogeneously adsorbed onto the surface of the film mainly composed of zinc oxide, at etching zinc oxide with the acidic component, a portion where the etching rate is fast and a portion where the etching rate is slow are produced, and a favorable texture is formed as compared with the case of performing etching with an acid alone. That is, it may be assumed that a favorable texture is formed through a combination of the polyacrylic acid or its salt and the acidic component.

### <<pH of Texture Processing Liquid>>

The texture processing liquid is an acidic aqueous solution, and its pH value is preferably not more than 6.5, and more preferably not more than 6. When the pH value is not more than 6.5, the etching rate is favorable, so that it does not take a long time for obtaining a desired recess and projection shape, and the productivity is favorable, and hence, such is preferable.

### [Production Method of Transparent Conductive Film]

The method for producing a transparent conductive film according to the present invention comprises fabricating a transparent conductive film mainly composed of zinc oxide on a substrate, bringing the transparent conductive film into contact with the texture processing liquid of the present invention to form a texture having recesses and projections on the surface of the transparent conductive film, and then subjecting the surface of the texture to a contact treatment with an alkaline aqueous solution having a pH value of 12 or more.

<<Etching Treatment with Texture Processing Liquid>>

A temperature in the contact treatment (etching treatment) between the texture processing liquid and the transparent conductive film in the production method of the present invention influences the etching rate of the transparent conductive film, and therefore, it is necessary to control the temperature on a fixed level. Accordingly, so far as the temperature of the processing liquid falls within the range of from 5° C. to 80° C., an etching effect is obtainable, and a texture is obtainable. The temperature of the processing liquid is more preferably in the range of from 10° C. to 70° C., and especially desirably in the range of from 15° C. to 50° C. When the temperature of the processing liquid is made to fall within the foregoing ranges, the dew condensation is not caused in an etching apparatus, and a change in the concentration of the etching liquid component due to the moisture evaporation does not occur, and hence, such is preferable.

Though a treatment time with the texture processing liquid is varied depending upon the concentration and temperature of the texture processing liquid, and so on, for example, it is from 30 seconds to 360 seconds, preferably from 60 seconds to 180 seconds, and especially preferably from 60 seconds to 120 seconds. According to the excessive treatment, the film thickness of the film mainly composed of zinc oxide becomes thin to cause an increase of the sheet resistance, and the photoelectric conversion efficiency is deteriorated, leading to a cause of a lowering of the photoelectric conversion efficiency.

<<Contact Treatment with Alkaline Aqueous Solution>>

In the production method of the present invention, after etching with the texture processing liquid of the present invention, an alkaline aqueous solution having a pH value of 12 or more is used. This is because when the pH value is less than 12, the treatment effect is insufficient, so that a high photoelectric conversion efficiency is not obtainable.

As the alkaline aqueous solution, an aqueous solution containing, for example, sodium hydroxide, potassium hydroxide, tetramethylammonium hydroxide, ammonia, monoethanolamine, methyl ethanolamine, or the like, is preferably exemplified. An aqueous solution of sodium hydroxide, potassium hydroxide, tetramethylammonium hydroxide or ammonia is more preferable, and an aqueous solution of potassium hydroxide, tetramethylammonium hydroxide or ammonia is especially preferable.

According to the contact treatment with the alkaline aqueous solution of the present invention, there is brought not only an effect in which by removing the polyacrylic acid and its salt adsorbed onto the surface of the film mainly composed of zinc oxide, the electric resistance at an interface thereof with a p-type amorphous silicon layer is reduced, but an effect in which in view of the fact that the surface of the film having recesses and projections is further etched, an undulated shape of the projection and the recess becomes smooth, whereby the coverage of the p-type amorphous silicon film is improved.

A treatment temperature of the alkaline aqueous solution influences the treatment effect, and therefore, it is necessary to control the temperature on a fixed level. Accordingly, so far as the temperature of the alkaline aqueous solution falls within the range of from 5° C. to 80° C., a favorable texture is obtainable. The temperature of the alkaline aqueous solution is more preferably in the range of from 10° C. to 70° C., and especially desirably in the range of from 15° C. to 50° C. When the temperature of the alkaline aqueous solution is made to fall within the foregoing ranges, the dew condensation is not caused in an etching apparatus, and a change in the concentration of the etching liquid component due to the moisture evaporation does not occur, and hence, such is preferable.

Though a treatment time with the alkaline aqueous solution is varied depending upon the concentration and temperature of the alkaline aqaueous solution, and so on, for example, it is from 1 second to 300 seconds, preferably from 2 seconds to 100 seconds, and especially preferably from 5 seconds to 60 seconds. According to the excessive treatment, a fine hole is generated in the film mainly composed of zinc oxide, and the coverage of the p-type amorphous silicon layer is deteriorated, leading to a cause of a lowering of the photoelectric conversion efficiency.

So far as the method for performing the contact treatment of the substrate with the texture processing liquid and the alkaline aqueous solution is a method in which the concentration, fluidized state and temperature of the chemical liquid on the substrate surface can be uniformly controlled, its form is not regarded. For example, a mode for dipping the substrate in a container filled with the chemical liquid may be adopted, or a mode for feeding the chemical liquid into the substrate using a spray nozzle, a slit nozzle or the like may be adopted.

### EXAMPLES

The present invention is hereunder described in more detail by reference to the following Examples and Comparative Example, but it should not be construed that the present invention is limited to these Examples.

The generating performance was measured with respect to the following items.

The generating performance evaluation was performed using a solar simulator YSS-50A, manufactured by Yamashita Denso Corporation, and a release voltage (Voc), a short-circuit current density (Jsc) a fill factor, a series resistance and a photoelectric conversion efficiency at an air mass of 1.5 were measured. That is, light with a certain intensity is irradiated. on a solar battery cell, a current-voltage curve is measured while controlling the voltage, and a short-circuit current value (Isc, unit: mA) and a release voltage value (Voc, unit: mV) are determined. At that time, the short-circuit current density (Jsc) expresses a short-circuit current value per unit area (unit: mA/cm²).

Next, a power-voltage curve is obtained from the calculation by the current-voltage curve, and a current and a voltage at the time of obtaining a maximum power are defined as an optimal current (Imax) and an optimal voltage (Vmax), respectively.

The fill factor is a value obtained by dividing the product of the optimal current (Imax) and the optimal voltage (Vmax) by the product of the short-circuit current value (Isc) and the release voltage value (Voc).

Then, the photoelectric conversion efficiency (%) is determined as the quotient of the incident energy into the solar cell relative to the product of the short-circuit current density, the release voltage and the fill factor by (0.1 W/cm² according to the JIS standards).

What the short-circuit current density (Jsc) is large means that recesses and projections are formed on the surface of the transparent conductive film, so that the optical confinement effect is high; and what the photoelectric conversion efficiency is high means that the efficiency of the solar cell is high.

Also, secondary electron images of the surfaces of the transparent conductive films of the thin film solar cells obtained in the Examples and Comparative Examples were observed with an observation magnification of 50,000 times using a scanning electron microscope (S5500 Model (model number), manufactured by Hitachi, Ltd.) (accelerating voltage: 2 kV).

### Example 1

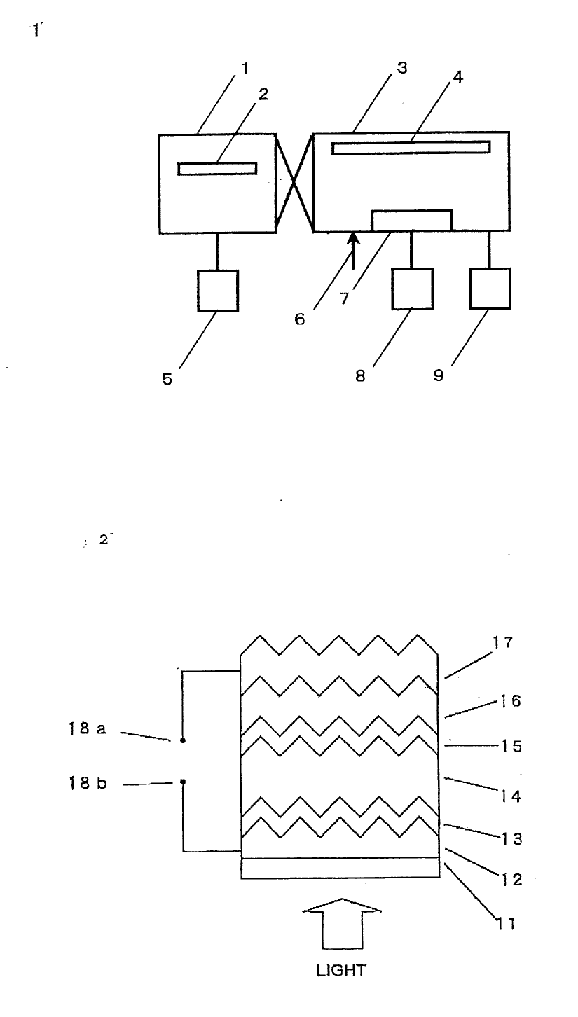

A diagrammatic sectional view of an apparatus used in the film formation of a transparent conductive film mainly composed of zinc oxide is shown in the diagrammatic view of film formation apparatus of FIGS. 1. (1) to (9) in FIG. 1 are as follows. (1) is a charge/discharge chamber; (2) is a substrate tray; (3) is a film formation chamber; (4) is a heater; (5) is a roughing exhaust system; (6) is a gas line; (7) is a cathode; (8) is a power source; and (9) is a high vacuum exhaust system.

First of all, a zinc oxide target having 2% by mass of aluminum oxide as an impurity added thereto was installed in the cathode (7), the heater (4) was set up so as to adjust a substrate temperature to 250° C., and the film formation chamber was heated. Thereafter, a non-alkaline glass substrate was charged in the charge/discharge chamber (1) and after being exhausted by the roughing exhaust system (5), conveyed into the film formation chamber (3). At that time, the film formation chamber (3) is kept high in vacuum by the high vacuum exhaust system (9). After introducing an argon gas as a process gas from the gas line (6), the zinc oxide target installed in the cathode (7) was sputtered by impressing a power to the cathode (7) using a DC power source, thereby depositing a zinc oxide based transparent conductive film in a film thickness of 1,000 nm on the non-alkaline glass substrate, and the substrate was then discharged from the charge/discharge chamber (1). The film surface was treated with a texture processing liquid A containing 5% by mass acetic acid (an SC grade, manufactured by Wako Pure Chemical Industries, Ltd.) and 0.6% by mass polyammonium acrylate (ARON A-30SL, manufactured by Toagosei Co., Ltd.) at a treatment temperature of 35° C. for a treatment time of 120 seconds while shaking the substrate in the texture processing liquid. The texture processing liquid composition is shown in Table 1, and the treatment condition is shown in Table 3.

Subsequently, a solar battery cell shown in FIG. 2 was fabricated on the surface of the zinc oxide film. First of all, an amorphous silicon semiconductor layer having a pin junction was subjected to film formation by means of CVD. Then, a gallium-doped zinc oxide film was subjected to film formation on the semiconductor layer by means of sputtering. Thereafter, silver was subjected to film formation as a back-side electrode by means of sputtering. The thus obtained thin film solar cell (light receiving area: 1 cm²) was irradiated with light at an air mass of 1.5 in an amount of light of 100 mW/cm², thereby measuring an output characteristic. The short-circuit current density was 12.66 mA/cm². The measurement results (short-circuit current density) are shown in Table 3.

### Example 2

Processing of the texture was performed under the same treatment condition as that in Example 1. Thereafter, dipping was performed using an alkaline aqueous solution A shown in Table 2 (5% by mass potassium hydroxide aqueous solution (a reagent grade, manufactured by Kanto Chemical Co., Inc.)) at a treatment temperature of 23° C. for 30 seconds. The thus obtained thin film solar cell (light receiving area: 1 cm²) was irradiated with light at an air mass of 1.5 in an amount of light of 100 mW/cm², thereby measuring an output characteristic. The short-circuit current density was 12.56 mA/cm². The measurement results (short-circuit current density) are shown in Table 3.

### Examples 3 to 11 and 16

Thin film solar cells were obtained in the same manner as in Example 2, except that in Example 2, the treatment with a texture processing liquid and the treatment with an alkaline aqueous solution were performed as shown in Table 3. Each of the thus obtained thin film solar cells (light receiving area: 1 cm²) was irradiated with light at an air mass of 1.5 in an amount of light of 100 mW/cm², thereby measuring an output characteristic. The measurement results (short-circuit current density) are shown in Table 3.

### Comparative Example 1

A thin film solar cell was obtained in the same manner as in Example 1, except that in Example 1, a processing liquid K (5% by mass acetic acid (with a balance being water)) as shown in Table 3 was used as the texture processing liquid. The thus obtained thin film solar cell (light receiving area: 1 cm²) was irradiated with light at an air mass of 1.5 in an amount of light of 100 mW/cm², thereby measuring an output characteristic. The measurement results (short-circuit current density) are shown in Table 3.

### Comparative Example 2

A thin film solar cell was obtained in the same manner as in Example 2, except that in Example 2, a processing liquid K (5% by mass acetic acid (with a balance being water)) as shown in Table 3 was used as the texture processing liquid. The thus obtained thin film solar cell (light receiving area: 1 cm²) was irradiated with light at an air mass of 1.5 in an amount of light of 100 mW/cm², thereby measuring an output characteristic. The measurement results (short-circuit current density) are shown in Table 3.

While Comparative Example 1 is concerned with the results obtained by the treatment with the processing liquid K (acetic acid solution), the short-circuit current density was 12.32 mA/cm². On the other hand, in view of the fact that the short-circuit current density of Example 1 using the same acidic component (acetic acid) increased to 12.66 mA/cm², it is noted that the optical confinement effect is increased by polyammonium acrylate.

Also, while Comparative Example 2 is concerned with an example in which after the treatment with the processing liquid K (acetic acid solution), in view of the fact that as compared with Examples 2 to 11 and 16 in which the same acidic component (acetic acid) was used, and the treatment with an alkaline aqueous solution was performed, the short-circuit current density (12.22 mA/cm²) is small, it is noted that the optical confinement effect is increased by polyammonium acrylate.

### Example 12 and Comparative Example 3

Thin film solar cells were obtained in the same manner as in Example 2, except that in Example 2, the treatment with a texture processing liquid and the treatment with an alkaline aqueous solution were performed as shown in Table 3. Each of the thus obtained thin film solar cells (light receiving area: 1 cm²) was irradiated with light at an air mass of 1.5 in an amount of light of 100 mW/cm², thereby measuring an output characteristic. The measurement results (short-circuit current density) are shown in Table 3.

Each of Example 12 and Comparative Example 3 is concerned with an example in which processing liquids G and L each containing tartaric acid as the acidic component were used, respectively. In view of the fact that the short-circuit current density of Example 12 is larger than the short-circuit current density of Comparative Example 3, it is noted that even when the acidic component in the processing liquid is tartaric acid, the optical confinement effect is increased by polyammonium acrylate.

### Example 13 and Comparative Example 4

Thin film solar cells were obtained in the same manner as in Example 2, except that in Example 2, the treatment with a texture processing liquid and the treatment with an alkaline aqueous solution were performed as shown in Table 3. Each of the thus obtained thin film solar cells (light receiving area: 1 cm²) was irradiated with light at an air mass of 1.5 in an amount of light of 100 mW/cm², thereby measuring an output characteristic. The measurement results (short-circuit current density) are shown in Table 3.

Each of Example 13 and Comparative Example 4 is concerned with an example in which processing liquids H and M each containing malic acid as the acidic component were used, respectively. In view of the fact that the short-circuit current density of Example 13 is larger than the short-circuit current density of Comparative Example 4, it is noted that even when the acidic component in the processing liquid is malic acid, the optical confinement effect is increased by polyammonium acrylate.

### Examples 14 and Comparative Example 5

Thin film solar cells were obtained in the same manner as in Example 2, except that in Example 2, the treatment with a texture processing liquid and the treatment with an alkaline aqueous solution were performed as shown in Table 3. Each of the thus obtained thin film solar cells (light receiving area: 1 cm²) was irradiated with light at an air mass of 1.5 in an amount of light of 100 mW/cm², thereby measuring an output characteristic. The measurement results (short-circuit current density) are shown in Table 3.

Each of Example 14 and Comparative Example 5 is concerned with an example in which processing liquids I and N each containing lactic acid as the acidic component were used, respectively. In view of the fact that the short-circuit current density of Example 14 is larger than the short-circuit current density of Comparative Example 5, it is noted that even when the acidic component in the processing liquid is lactic acid, the optical confinement effect is increased by polyammonium acrylate.

### Example 15 and Comparative Example 6

Thin film solar cells were obtained in the same manner as in Example 2, except that in Example 2, the treatment with a texture processing liquid and the treatment with an alkaline aqueous solution were performed as shown in Table 3. Each of the thus obtained thin film solar cells (light receiving area: 1 cm²) was irradiated with light at an air mass of 1.5 in an amount of light of 100 mW/cm², thereby measuring an output characteristic. The measurement results (short-circuit current density) are shown in Table 3.

Each of Example 15 and Comparative Example 6 is concerned with an example in which processing liquids J and O each containing citric acid as the acidic component were used, respectively. In view of the fact that the short-circuit current density of Example 15 is larger than the short-circuit current density of Comparative Example 6, it is noted that even when the acidic component in the processing liquid is citric acid, the optical confinement effect is increased by polyammonium acrylate.

TABLE 1

| | Texture processing liquid | | | | | |
|---|---|---|---|---|---|---|
| | Acidic component | | Polyacrylic acid or its salt | | | |
| | Kind | % by mass | | % by mass | Balance | pH |
| Processing liquid A | Acetic acid | 5.0 | Polyammonium acrylate ^{*1} | 0.6 | Water | 3.5 |
| Processing liquid B | Acetic acid | 5.0 | Polyammonium acrylate ^{*1} | 0.6 | Water | 6.0 |
| Processing liquid C | Acetic acid | 5.0 | Polyacrylic acid ^{*2} | 0.2 | Water | 3.5 |
| Processing liquid D | Acetic acid | 5.0 | Polyammonium acrylate ^{*3} | 0.4 | Water | 3.6 |
| Processing liquid E | Acetic acid | 0.05 | Polyammonium acrylate ^{*1} | 0.6 | Water | 3.5 |
| Processing liquid F | Acetic acid | 30 | Polyammonium acrylate ^{*1} | 0.6 | Water | 1.9 |
| Processing liquid G | Tartaric acid | 5.0 | Polyammonium acrylate ^{*1} | 0.6 | Water | 2.3 |
| Processing liquid H | Malic acid | 5.0 | Polyammonium acrylate ^{*1} | 0.6 | Water | 2.6 |
| Processing liquid I | Lactic acid | 5.0 | Polyammonium acrylate ^{*1} | 0.6 | Water | 2.7 |
| Processing liquid J | Citric acid | 5.0 | Polyammonium acrylate ^{*1} | 0.6 | Water | 2.5 |
| Processing liquid K | Acetic acid | 5.0 | — | — | Water | 2.4 |
| Processing liquid L | Tartaric acid | 5.0 | — | — | Water | 1.7 |
| Processing liquid M | Malic acid | 5.0 | — | — | Water | 1.9 |
| Processing liquid N | Lactic acid | 5.0 | — | — | Water | 2.0 |
| Processing liquid 0 | Citric acid | 5.0 | — | — | Water | 1.8 |
| Processing liquid P | Acetic acid | 5.0 | Polyethylene glycol ^{*4} | 0.6 | Water | 3.5 |
| Processing liquid Q | Acetic acid | 5.0 | Polyvinyl alcohol ^{*5} | 0.6 | Water | 3.5 |

^{*1}: ARON A-30SL (a trade name) , manufactured by Toagosei Co., Ltd. , weight average molecular weight: 6,000
^{*2}: Polyacrylic acid, manufactured by Sigma-Aldrich Japan K.K. , weight average molecular weight: 2,000
^{*3}: SHALLOL AH-103P (a trade name) , manufactured by Dai-ichi Kogyo Seiyaku Co., Ltd., weight average molecular
weight: 10,000
^{*4}: Manufactured by Wako Pure Chemical Industries, Ltd. , weight average molecular weight: 6,000
^{*5}: Manufactured by Wake Pure Chemical Industries, Ltd., weight average molecular weight: 2,000

TABLE 2
Alkaline aqueous solution

| | Kind | Content (% by mass) | pH |
|---|---|---|---|
| Aqueous solution A | Potassium hydroxide | 5.0 | 14.0 |
| | aqueous solution | | |
| Aqueous solution B | Potassium hydroxide | 0.1 | 12.7 |
| | aqueous solution | | |
| Aqueous solution C | Monoethanolamine | 5.2 | 12.4 |
| | aqueous solution | | |
| Aqueous solution D | Tetramethylammonium | 7.8 | 14.0 |
| | hydroxyide aqueous | | |
| | solution | | |
| Aqueous solution E | Ammonia aqueous | 3.0 | 12.2 |
| | solution | | |
| Aqueous solution F | Potassium hydroxide | 5.0 | 11.2 |
| | aqueous solution with | | |
| | carbonic acid being blown | | |

TABLE 3

| | Texture processing liquid | | | Alkaline aqueous solution | | Short-circtit current |
|---|---|---|---|---|---|---|
| | Processing liquid | Acidic component | Treatment condition, | Aqueous solution | Treatment condition | density Jsc (mA/cm²) |
| Example 1 | Processing liquid A | Acetic add | 35° C., 120 seconds | — | — | 12.66 |
| Example 2 | Processing liquid A | Acetic add | 35° C., 120 seconds | Aqueous solution A | 23° C., 30 seconds | 12.56 |
| Example 3 | Processing liquid A | Acetic acid | 35° C., 120 seconds | Aqueous solution B | 23° C., 30 seconds | 14.74 |
| Example 4 | Processing liquid A | Acetic add | 35° C., 120 seconds | Aqueous solution C | 23° C., 30 seconds | 15.16 |
| Example 5 | Processing liquid A | Acetic add | 35° C., 120 seconds | Aqueous solution D | 23° C., 30 seconds | 14.71 |
| Example 6 | Processing liquid A | Acetic add | 35° C., 120 seconds | Aqueous solution E | 23° C., 30 seconds | 15.28 |
| Example 7 | Processing liquid B | Acetic add | 35° C., 120 seconds | Aqueous solution A | 23° C., 30 seconds | 12.40 |
| Example 8 | Processing liquid C | Acetic add | 35° C., 120 seconds | Aqueous solution A | 23° C., 30 seconds | 12.66 |
| Example 9 | Processing liquid D | Acetic add | 35° C., 120 seconds | Aqueous solution A | 23° C., 30 seconds | 13.41 |
| Example 10 | Processing liquid E | Acetic add | 35° C., 360 seconds | Aqueous solution A | 23° C., 30 seconds | 12.59 |
| Example 11 | Processing liquid F | Acetic add | 35° C., 120 seconds | Aqueous solution A | 23° C., 30 seconds | 12.73 |
| Example 16 | Processing liquid A | Acetic add | 35° C., 120 seconds | Aqueous solution F | 23° C., 30 seconds | 12.72 |
| Comparative Example 1 | Processing liquid K | Acetic add | 35° C., 120 seconds | — | — | 12.32 |
| Comparative Example 2 | Processing liquid K | Acetic acid | 35° C., 120 seconds | Aqueous solution A | 23° C., 30 seconds | 12.22 |
| Example 12 | Processing liquid G | Tartaric acid | 35° C., 60 seconds | Aqueous solution A | 23° C., 30 seconds | 12.84 |
| Comparative Example 3 | Processing liquid L | Tartaric acid | 35° C., 120 seconds | Aqueous solution A | 23° C., 30 seconds | 11.53 |
| Example 13 | Processing liquid H | Matic acid | 35° C., 60 seconds | Aqueous solution A | 23° C., 30 seconds | 13.11 |
| Comparative Example 4 | Processing liquid M | Malic acid | 35° C., 120 seconds | Aqueous solution A | 23° C., 30 seconds | 11.88 |
| Example 14 | Processing liquid I | Lactic acid | 35° C., 90 seconds | Aqueous solution A | 23° C., 30 seconds | 14.15 |
| Comparative Example 5 | Processing liquid N | Lactic acid | 35° C., 120 seconds | Aqueous solution A | 23° C., 30 seconds | 12.50 |
| Example 15 | Processing liquid J | Citric acid | 35° C., 90 seconds | Aqueous solution A | 23° C., 30 seconds | 14.64 |
| Comparative Example 6 | Processing liquid O | Cilric acid | 35° C., 60 seconds | Aqueous solution A | 23° C., 30 seconds | 13.35 |

### Example 17

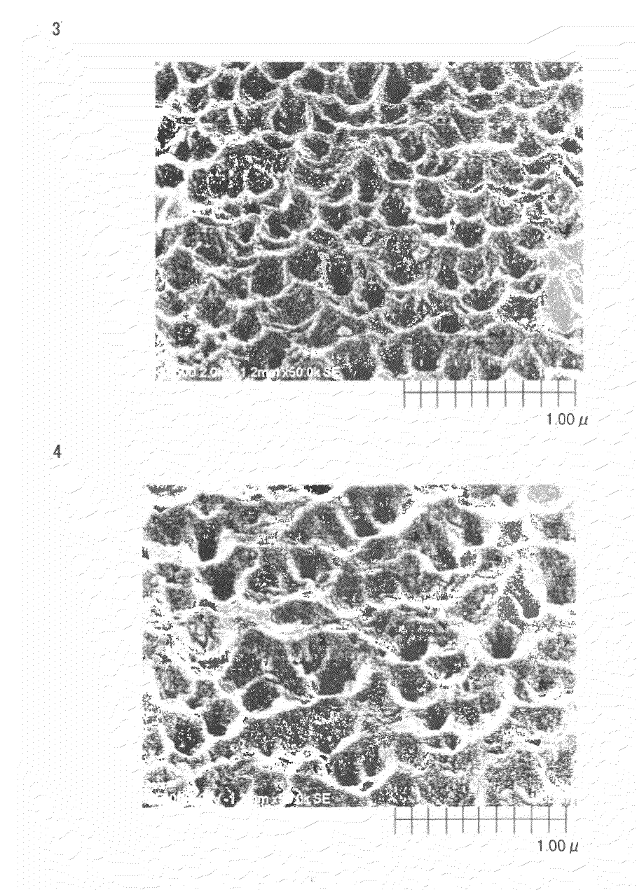

After processing of the texture was performed using the processing liquid A shown in Table 1 under the same treatment condition as that in Example 1, dipping was performed using the alkaline aqueous solution A shown in Table 2 (5% by mass potassium hydroxide aqueous solution (a reagent grade, manufactured by Kanto Chemical Co., Inc.)) at a treatment temperature of 23° C. for 30 seconds. The thus obtained thin film solar cell (light receiving area: 1 cm²) was irradiated with light at an air mass of 1.5 in an amount of light of 100 mW/cm², thereby measuring an output characteristic. The short-circuit current density, release voltage, fill factor, series resistance and photoelectric conversion efficiency are shown in Table 5. Also, a secondary electron image of the surface of the transparent conductive film of the thin film solar cell obtained in Example 17 was observed (see FIG. 3).

### Example 18

A thin film solar cell was obtained in the same manner as in Example 17, except that in Example 17, the treatment with a texture processing liquid and the treatment with an alkaline aqueous solution were performed as shown in Table 4. The thus obtained thin film solar cell (light receiving area: 1 cm²) was irradiated with light at an air mass of 1.5 in an amount of light of 100 mW/cm², thereby measuring an output characteristic. The short-circuit current density, release voltage, fill factor, series resistance and photoelectric conversion efficiency are shown in Table 5. In the thin film solar cell obtained in Example 18, the photoelectric conversion efficiency was favorable similar to that in Example 17, and the effects of the present invention were confirmed. Also, a secondary electron image of the surface of the transparent conductive film of the thin film solar cell obtained in Example 18 was observed (see FIG. 4).

### Comparative Examples 7 to 10

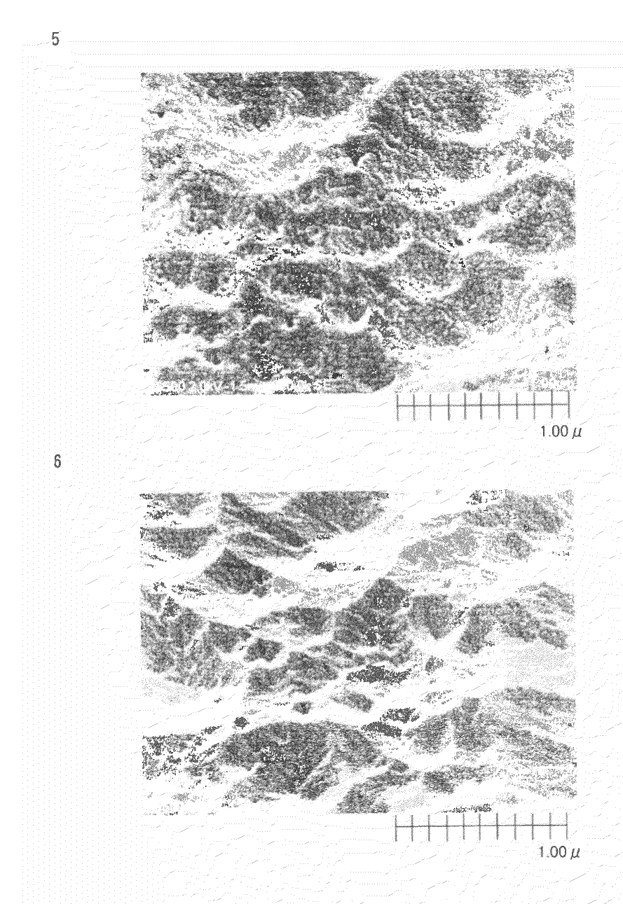

Thin film solar cells were obtained in the same manner as in Example 17, except that in Example 17, the treatment with a texture processing liquid was performed as shown in Table 4, whereas the treatment with an alkaline aqueous solution was not performed. Each of the thus obtained thin film solar cells (light receiving area: 1 cm²) was irradiated with light at an air mass of 1.5 in an amount of light of 100 mW/cm², thereby measuring an output characteristic. The short-circuit current density, release voltage, fill factor, series resistance and photoelectric conversion efficiency are shown in Table 5. Also, a secondary electron image of the surface of the transparent conductive, film of each of the thin film solar cells obtained in Comparative Examples 7 and 8 was observed (see FIGS. 5 and 6, respectively).

### Comparative Examples 11 and 12

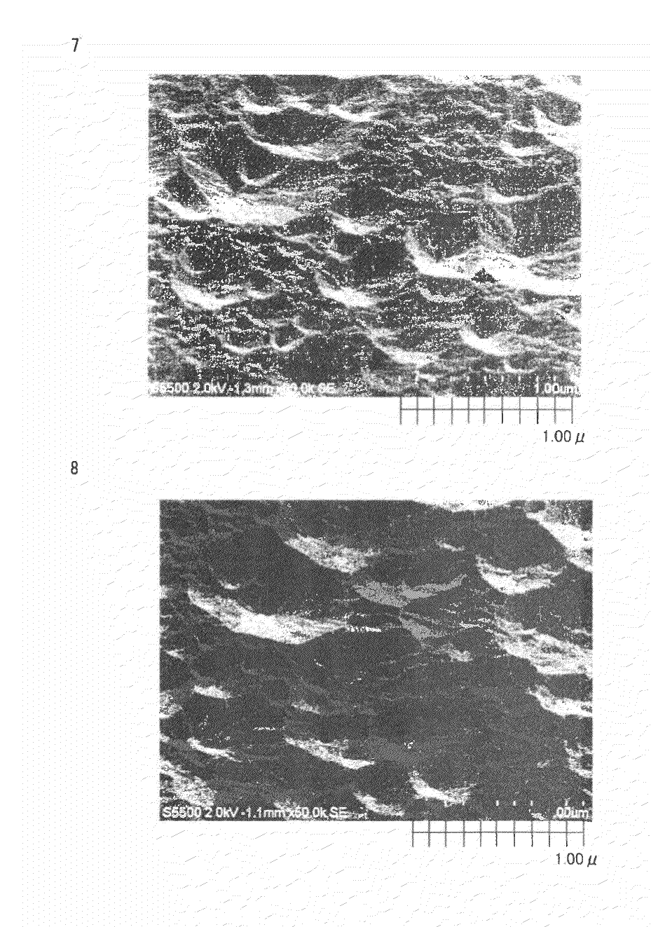

Thin film solar cells were obtained in the same manner as in Example 17, except that in Example 17, the treatment with a texture processing liquid was performed as shown in Table 4, whereas the treatment with an alkaline aqueous solution was not performed. A secondary electron image of the surface of the transparent conductive film of each of the obtained thin film solar cells was observed (see FIGS. 7 and 8, respectively).

While Comparative Example 7 is concerned with an example in which after the treatment with the processing liquid K (acetic acid solution), the treatment with an alkaline aqueous solution was not performed, the short-circuit current density was 12.32 mA/cm², and the photoelectric conversion efficiency was 6.87%. On the other hand, in Example 17, in view of the fact that not only the short-circuit current density is 12.56 mA/cm², but the photoelectric conversion efficiency is 7.74%, it is noted that the short-circuit current density is increased by polyammonium acrylate in the processing liquid (the optical confinement effect is increased) and that the photoelectric conversion efficiency is increased due to a synergistic effect with the effect by the alkaline aqueous solution.

While Comparative Example 8 is concerned with an example in which after the treatment with the processing liquid A (processing liquid containing acetic acid and polyammonium acrylate), the treatment with an alkaline aqueous solution was not performed, in view of the fact that though the short-circuit current density is slightly larger than that in Example 17, the series resistance is large, and the fill factor is small, the photoelectric conversion efficiency was consequently a small value as 3.92%. In Example 17, in view of the fact though the short-circuit current density is slightly smaller than that in Comparative Example 2, the series resistance is small, and the fill factor is large, it may be considered that the texture having an effective recess and projection shape on the surface of zinc oxide was formed due to a synergistic effect between the treatment with polyammonium acrylate and the treatment with an alkaline aqueous solution, the series resistance was reduced, and the fill factor was increased, whereby the photoelectric conversion efficiency became high.

While Comparative Example 9 is concerned with an example in which after the treatment with the processing liquid K (acetic acid solution), the treatment with an alkaline aqueous was performed, the values of the short-circuit current density and the photoelectric conversion efficiency were smaller than those in Example 17. According to this, an effect due to the addition of a polyacrylic acid is revealed.

Also, while Comparative Example 10 is concerned with an example in which after the treatment with the processing liquid A (processing liquid containing acetic acid, and polyammonium acrylate), carbonic acid was blown to perform the treatment with an alkaline aqueous solution at a pH of 11.2, in view of the fact that though the short-circuit current density is slightly larger than that in Example 17, the series resistance is large, and the fill factor is small, the photoelectric conversion efficiency was consequently a small value as 4.49%. That is, it is noted that in the treatment with an alkaline aqueous solution having a pH of less than 12, there is no effect for increasing the photoelectric conversion efficiency.

Secondary electron images (observation magnification: 50, 000 times) with respect to Examples 17 and 18 and Comparative Examples 7, 8, 11 and 12 are shown in FIGS. 3 to 8, respectively. From FIGS. 3 and 4, in the surface of the transparent conductive film in each of the thin film solar cells obtained in the Examples, a scaly shape having an approximate diameter of from about 0.1 to 0.5 μm, a pitch size of recesses and projections of from about 0.2 to 0.4 μm and a depth of recesses and projections of from about 0.1 to 0.2 μm is distinctly observed, and a texture having an effective recess and projection shape is formed. According to this, it is noted that the optical confinement effect and the photoelectric conversion efficiency are excellent. On the other hand, in Comparative Examples 7 and 8 (FIGS. 5 and 6) in which the treatment with an alkaline aqueous solution was not performed, the texture on the surface of the transparent conductive film is indistinct, and it is noted that a texture having an effective recess and projection shape was not formed. Also, in Comparative Examples 11 and 12 using a polyacrylic acid-free texture processing liquid, the texture on the surface of the transparent conductive film is indistinct, a texture having an effective recess and projection shape is not formed, and it is noted that according to the addition of a water-soluble polymer other than the polyacrylic acid or its salt, the optical confinement effect is not sufficiently obtainable.

### Examples 19 to 26

Thin film solar cells were obtained in the same manner as in Example 2, except that in Example 17, the treatment with a texture processing liquid and the treatment with an alkaline aqueous solution were performed as shown in Table 4. Each of the thus obtained thin film solar cells (light receiving area: 1 cm²) was irradiated with light at an air mass of 1.5 in an amount of light of 100 mW/cm², thereby measuring an output characteristic. The short-circuit current density, release voltage, fill factor, series resistance and photoelectric conversion efficiency are shown in Table 5. The photoelectric conversion efficiency was favorable similar to that in Example 17, and the effects of the present invention can be confirmed.

### Example 27 and Comparative Example 13

Thin film solar cells were obtained in the same manner as in Example 2, except that in Example 17, the treatment with a texture processing liquid and the treatment with an alkaline aqueous solution were performed as shown in Table 4. Each of the thus obtained thin film solar cells (light receiving area: 1 cm²) was irradiated with light at an air mass of 1.5 in an amount of light of 100 mW/cm², thereby measuring an output characteristic. The short-circuit current density, release voltage, fill factor, series resistance and photoelectric conversion efficiency are shown in Table 5.

Each of Example 27 and Comparative Example 13 is concerned with an example in which processing liquids G and L each containing tartaric acid as the acidic component were used, respectively. In view of the fact that the short-circuit current density and photoelectric conversion efficiency of Example 27 are larger than those of Comparative Example 13, it is noted that the optical confinement effect is increased by polyammonium acrylate, and the photoelectric conversion efficiency is also increased.

### Example 28 and Comparative Example 14

Thin film solar cells were obtained in the same manner as in Example 2, except that in Example 17, the treatment with a texture processing liquid and the treatment with an alkaline aqueous solution were performed as shown in Table 4. Each of the thus obtained thin film solar cells (light receiving area: 1 cm²) was irradiated with light at an air mass of 1.5 in an amount of light of 100 mw/cm², thereby measuring an output characteristic. The short-circuit current density, release voltage, fill factor, series resistance and photoelectric conversion efficiency are shown in Table 5.

Each of Example 28 and Comparative Example 14 is concerned with an example in which processing liquids H and M each containing malic acid as the acidic component were used, respectively. In view of the fact that the short-circuit current density and photoelectric conversion efficiency of Example 28 are larger than those of Comparative Example 14, it is noted that the optical confinement effect is increased by polyammonium acrylate, and the photoelectric conversion efficiency is also increased.

### Example 29 and Comparative Example 15

Thin film solar cells were obtained in the same manner as in Example 2, except that in Example 17, the treatment with a texture processing liquid and the treatment with an alkaline aqueous solution were performed as shown in Table 4. Each of the thus obtained thin film solar cells (light receiving area: 1 cm²) was irradiated with light at an air mass of 1.5 in an amount of light of 100 mW/cm², thereby measuring an output characteristic. The short-circuit current density, release voltage, fill factor, series resistance and photoelectric conversion efficiency are shown in Table 5.

Each of Example 29 and Comparative Example 15 is concerned with an example in which processing liquids I and N each containing lactic acid as the acidic component were used, respectively. In view of the fact that the short-circuit current density and photoelectric conversion efficiency of Example 29 are larger than those of Comparative Example 15, it is noted that the optical confinement effect is increased by polyammonium acrylate, and the photoelectric conversion efficiency is also increased.

### Example 30 and Comparative Example 16

Thin film solar cells were obtained in the same manner as in Example 2, except that in Example 17, the treatment with a texture processing liquid and the treatment with an alkaline aqueous solution were performed as shown in Table 4. Each of the thus obtained thin film solar cells (light receiving area: 1 cm²) was irradiated with light at an air mass of 1.5 in an amount of light of 100 mW/cm², thereby measuring an output characteristic. The short-circuit current density, release voltage, fill factor, series resistance and photoelectric conversion efficiency are shown in Table 5.

Each of Example 30 and Comparative Example 16 is concerned with an example in which processing liquids J and O each containing citric acid as the acidic component were used, respectively. In view of the fact that the short-circuit current density and photoelectric conversion efficiency of Example 30 are larger than those of Comparative Example 16, it is noted that the optical confinement effect is increased by polyammonium acrylate, and the photoelectric conversion efficiency is also increased.

TABLE 4

| | Texture processing liquid | | | Alkaline aqueous solution | |
|---|---|---|---|---|---|
| | Processing liquid | Acidic component | Treatment condition | Aqueous solution | Treatment condition |
| Example 17 | Processing liquid A | Acetic acid | 35° C., 120 seconds | Aqueous solution A | 23° C., 30 seconds |
| Example 18 | Processing liquid A | Acetic acid | 35° C., 120 seconds | Aqueous solution B | 23° C., 30 seconds |
| Example 19 | Processing liquid A | Acetic acid | 35° C., 120 seconds | Aqueous solution C | 23° C., 30 seconds |
| Example 20 | Processing liquid A | Acetic acid | 35° C., 120 seconds | Aqueous solution D | 23° C., 30 seconds |
| Example 21 | Processing liquid A | Acetic acid | 35° C., 120 seconds | Aqueous solution E | 23° C., 30 seconds |
| Example 22 | Processing liquid B | Acetic acid | 35° C., 120 seconds | Aqueous solution A | 23° C., 30 seconds |
| Example 23 | Processing liquid C | Acetic acid | 35° C., 120 seconds | Aqueous solution A | 23° C., 30 seconds |
| Example 24 | Processing liquid D | Acetic acid | 35° C., 120 seconds | Aqueous solution A | 23° C., 30 seconds |
| Example 25 | Processing liquid E | Acetic acid | 35° C., 360 seconds | Aqueous solution A | 23° C., 30 seconds |
| Example 26 | Processing liquid F | Acetic acid | 35° C., 120 seconds | Aqueous solution A | 23° C., 30 seconds |
| Comparative | Processing liquid K | Acetic acid | 35° C., 120 seconds | — | — |
| Example 7 | | | | | |
| Comparative | Processing liquid A | Acetic acid | 35° C., 120 seconds | — | — |
| Example 8 | | | | | |
| Comparative | Processing liquid K | Acetic acid | 35° C., 120 seconds | Aqueous solution A | 23° C., 30 seconds |
| Example 9 | | | | | |
| Comparative | Processing liquid A | Acetic acid | 35° C., 120 seconds | Aqueous solution F | 23° C., 30 seconds |
| Example 10 | | | | | |
| Comparative | Processing liquid P | Acetic acid | 35° C., 120 seconds | Aqueous solution A | 23° C., 30 seconds |
| Example 11 | | | | | |
| Comparative | Processing liquid Q | Acetic acid | 35° C., 120 seconds | Aqueous solution A | 23° C., 30 seconds |
| Example 12 | | | | | |
| Example 27 | Processing liquid G | Tartaric acid | 35° C., 60 seconds | Aqueous solution A | 23° C., 30 seconds |
| Comparative | Processing liquid L | Tartaric acid | 35° C., 120 seconds | Aqueous solution A | 23° C., 30 seconds |
| Example 13 | | | | | |
| Example 28 | Processing liquid H | Malic acid | 35° C., 60 seconds | Aqueous solution A | 23° C., 30 seconds |
| Comparative | Processing liquid M | Malic acid | 35° C., 120 seconds | Aqueous solution A | 23° C., 30 seconds |
| Example 14 | | | | | |
| Example 29 | Processing liquid I | Lactic acid | 35° C., 90 seconds | Aqueous solution A | 23° C., 30 seconds |
| Comparative | Processing liquid N | Lactic acid | 35° C., 120 seconds | Aqueous solution A | 23° C., 30 seconds |
| Example 15 | | | | | |
| Example 30 | Processing liquid J | Citric acid | 35° C., 90 seconds | Aqueous solution A | 23° C., 30 seconds |
| Comparative | Processing liquid O | Citric acid | 35° C., 60 seconds | Aqueous solution A | 23° C., 30 seconds |
| Example 16 | | | | | |

TABLE 5

| | Short-circuit | Release | | Series | Photoelectric |
|---|---|---|---|---|---|
| | current | voltage | | resis- | conversion |
| | density | Voc | Fill | tance | efficiency |
| | Jsc (mA/cm²) | (mV) | factor | (Ω) | (%) |
| Example 17 | 12.56 | 868 | 0.71 | 33 | 7.74 |
| Example 18 | 14.74 | 810 | 0.64 | 41 | 7.64 |
| Example 19 | 15.16 | 710 | 0.67 | 26 | 7.21 |
| Example 20 | 14.71 | 759 | 0.68 | 26 | 7.59 |
| Example 21 | 15.28 | 738 | 0.69 | 22 | 7.78 |
| Example 22 | 12.40 | 869 | 0.73 | 29 | 7.87 |
| Example 23 | 12.66 | 850 | 0.67 | 25 | 7.21 |
| Example 24 | 13.41 | 842 | 0.65 | 34 | 7.34 |
| Example 25 | 12.59 | 875 | 0.73 | 17 | 8.04 |
| Example 26 | 12.73 | 862 | 0.71 | 19 | 7.79 |
| Comparative | 12.32 | 871 | 0.64 | 82 | 6.87 |
| Example 7 | | | | | |
| Comparative | 12.66 | 793 | 0.39 | 164 | 3.92 |
| Example 8 | | | | | |
| Comparative | 12.22 | 877 | 0.64 | 73 | 6.86 |
| Example 9 | | | | | |
| Comparative | 12.72 | 785 | 0.45 | 121 | 4.49 |
| Example 10 | | | | | |
| Example 27 | 12.84 | 874 | 0.69 | 40 | 7.74 |
| Comparative | 11.53 | 883 | 0.67 | 46 | 6.82 |
| Example 13 | | | | | |
| Example 28 | 13.11 | 857 | 0.74 | 27 | 8.31 |
| Comparative | 11.88 | 871 | 0.72 | 32 | 7.45 |
| Example 14 | | | | | |
| Example 29 | 14.15 | 794 | 0.70 | 34 | 7.86 |
| Comparative | 12.50 | 879 | 0.69 | 44 | 7.58 |
| Example 15 | | | | | |
| Example 30 | 14.64 | 876 | 0.67 | 40 | 8.59 |
| Comparative | 13.35 | 870 | 0.68 | 32 | 7.90 |
| Example 16 | | | | | |

### INDUSTRIAL APPLICABILITY

In a manufacturing process of a solar cell including a transparent electrode layer mainly composed of zinc oxide, by bringing the surface of a transparent electrode layer mainly composed of zinc oxide into contact with a processing liquid containing a polyacrylic acid or a salt thereof and an acidic component to give a texture having recesses and projections onto the surface of the transparent electrode layer and further subjecting it to a contact treatment with an alkaline aqueous solution, a recess and projection shape having not only a high optical confinement effect but favorable coverage can be fabricated, and a thin film solar cell with a high photoelectric conversion efficiency can be manufactured.

1. A texture processing liquid, comprising an acidic aqueous solution comprising:
a polyacrylic acid or a salt of polyacrylic acid; and
an acidic component,
wherein the texture processing liquid is suitable for forming a texture having recesses and projections on the surface of a transparent conductive film mainly comprising zinc oxide in a manufacturing process of a solar cell comprising the transparent conductive film.

2. The texture processing liquid of claim 1, wherein a pH value of the acidic aqueous solution is not more than 6.5.

3. The texture processing liquid of claim 1, wherein the polyacrylic acid is present and a weight average molecular weight of the polyacrylic acid is from 2,000 to 10,000.

4. The texture processing liquid of claim 1, wherein the salt of polyacrylic acid is present and is polyammonium acrylate.

5. The texture processing liquid of claim 1, wherein a concentration of the polyacrylic acid or the salt of polyacrylic acid is from 0.1% by mass to 3.0% by mass.

6. The texture processing liquid of claim 1, wherein the acidic component is at least one member selected from the group consisting of acetic acid, citric acid, lactic acid, malic acid, glycolic acid, tartaric acid, hydrochloric acid, sulfuric acid, and nitric acid.

7. The texture processing liquid of claim 1, wherein a concentration of the acidic component is from 0.01% by mass to 30% by mass of the texture processing liquid.

8. A method for producing a transparent conductive film, comprising:
fabricating a transparent conductive film mainly comprising zinc oxide on a substrate;
bringing the transparent conductive, film into contact with the texture processing liquid of claim 1 to form a texture having recesses and projections on the surface of the transparent conductive film; and then
subjecting the surface of the texture to a contact treatment with an alkaline aqueous solution having a pH value of 12 or more.

9. The method of claim 8, wherein the alkaline aqueous solution comprises at least one member selected from the group consisting of sodium hydroxide, potassium hydroxide, tetramethylammonium hydroxide, ammonia, monoethanolamine, and methyl ethanolamine.

10. The method of claim 8, wherein the transparent conductive film is one suitable for solar cells.

11. The texture processing liquid of claim 1, wherein a concentration of the acidic component is from 0.05% by mass to 10% by mass of the texture processing liquid.

12. The texture processing liquid of claim 1, wherein a concentration of the acidic component is from 0.1% by mass to 5% by mass of the texture processing liquid.

13. The texture processing liquid of claim 1, wherein the polyacrylic acid is present and a weight average molecular weight of the polyacrylic acid is from 3,000 to 8,000.

14. The texture processing liquid of claim 1, wherein the polyacrylic acid is present and a weight average molecular weight of the polyacrylic acid is from 4,000 to 6,000.

15. The texture processing liquid of claim 1, wherein a concentration of the polyacrylic acid or the salt of polyacrylic acid is from 0.2% by mass to 2.0% by mass.

16. The texture processing liquid of claim 1, wherein a concentration of the polyacrylic acid or the salt of polyacrylic acid is from 0.3% by mass to 1% by mass.

17. The texture processing liquid of claim 1, wherein a pH value of the acidic aqueous solution is not more than 6.
